(19) United States
(12) Patent Application Publication
(10) Pub. No.: US 2007/0121309 A1
(43) Pub. Date: May 31, 2007

(54) Shielding device

(75) Inventors: Ji-En Long, ShenZhen (CN); Wei-Nan Kuo, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/606,534

(22) Filed: Nov. 30, 2006

(30) Foreign Application Priority Data
Nov. 30, 2005 (CN) 200520134139.1

(51) Int. Cl. H05K 9/00

(52) U.S. Cl. 361/818

(57) ABSTRACT

A shielding device (1) comprises a top cover (11) and a frame (10). The top cover comprises a body portion (110) and a plurality of flanges (111) extends downward from outer edges of the body portion. A dome shaped projection (114) is formed in a central portion of the flange (111). The frame comprises a narrow top wall (100) and a side wall (101) depending downward from an edge of the top wall. An ellipse shaped mounting hole (102) is formed through the side wall for detachably engaging with corresponding projection (114) to the top cover.

### BACKGROUND OF THE INVENTION

1. Field of the Invention

The present invention relates to a shielding device, and particularly to a shielding device for providing EMI (electromagnetic interference) protection for electronic components on a circuit board.

2. Description of the Prior Art

U.S. Pat. No. 6,711,032 B2 discloses a conventional shielding device comprising a cover and a base frame mounted on a printed circuit board (PCB). A plurality of flanges are bended from outer edges of the cover and define multiple apertures extending therethrough. The base frame comprises side walls with a plurality of outwardly dome shaped projections for engaging with the apertures when the shielding device is in closed position. The projections can firmly engaging with the apertures in a height direction of the shielding device, and wherein the dimension of the apertures in the longitude direction is larger than that of the projections. However, since the projections are formed in the frame by stamping process, the frame is sometimes troublesome to provide excellent flatness when mounted on the PCB, thereby increasing the cost of the manufacture.

Thus there is a need for an improved shielding device which can overcome the disadvantage of the prior art.

### BRIEF SUMMARY OF THE INVENTION

It is an object of the present invention to provide a shielding device with excellent flatness and low cost.

To fulfill the above-mentioned objects, according to a preferred embodiment of the present invention, a shielding device comprises a frame and a top cover enclosing the frame. The frame comprises a top wall and a plurality of side walls depending downwardly from the top wall. The side walls comprise a plurality of ellipse shaped mounting holes defined therethrough. The top cover comprises a body portion and a plurality of flanges extending downward from the body portion. The flanges define a plurality of dome shaped projections and a plurality of half ball shaped protrusions all projecting inwardly from the central portions of the flanges. The projections can firmly engaging with the mounting holes in a height direction, and wherein the dimension of mounting holes in a longitude direction is lager than that of the projections, thereby providing a wide possible engaging area. So it doesn't need precisely mating relationship between the projections and the mounting holes and facilitates the assembled process of the shielding device. Besides, the protrusions are intervening with the frame and form a small gap between the frame and top cover, thereby it is easy to disassemble the shielding device. Further more, the projections are disposed on the top cover instead of the frame, thereby providing excellent flatness of the frame and decreasing the cost of the manufacture.

Other objects, advantages and novel features of the invention will become more apparent from the following detailed description of the present embodiment when taken in conjunction with the accompanying drawings.

### BRIEF DESCRIPTION OF THE DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 is a perspective view of a shielding device in accordance with the present invention;

FIG. 2 is another perspective view of FIG. 1;

FIG. 3 is an exploded view of the shielding device in accordance with the present invention;

FIG. 4 is another exploded view of FIG. 3;

FIG. 5 is a partly view of the shielding device according to the present invention;

FIG. 6 is a partly cross-sectional view of the edge of the shielding device taken along line 6-6 of FIG. 1; and

FIG. 7 is a partly cross-sectional view of the edge of the shielding device taken along line 7-7 of FIG. 1.

### DETAILED DESCRIPTION OF THE INVENTION

Reference will now be made in detail to the preferred embodiment of the present invention.

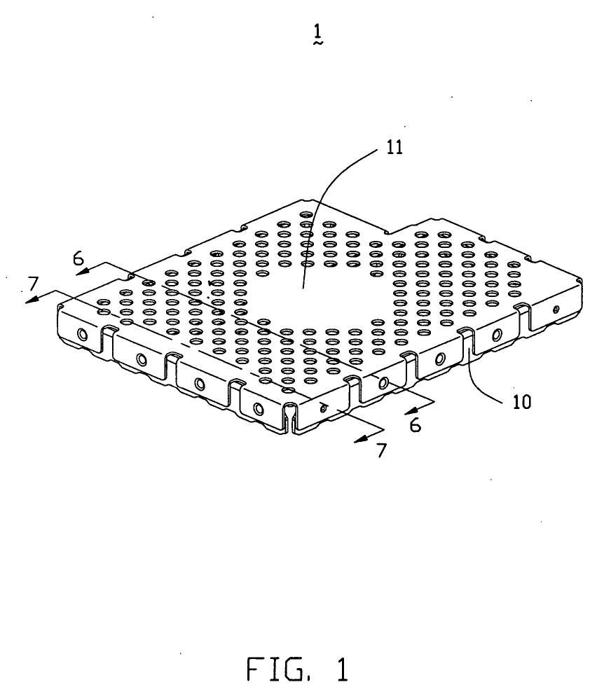

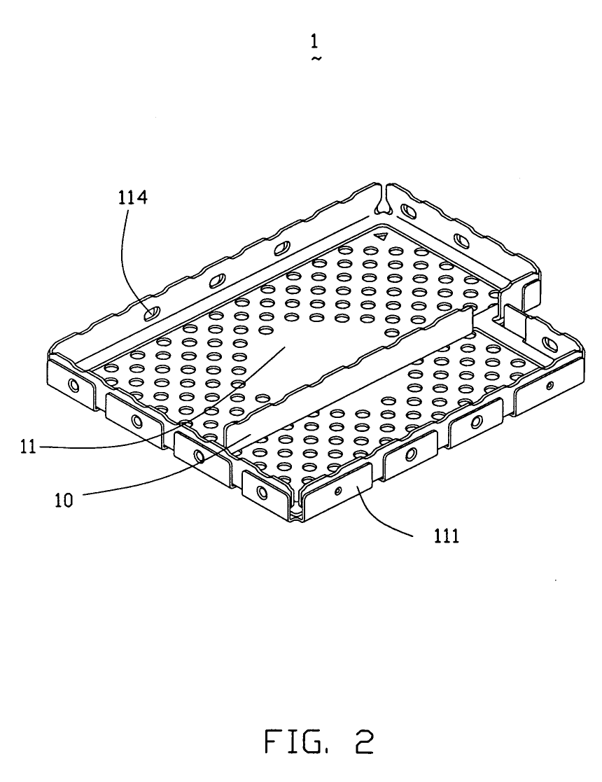

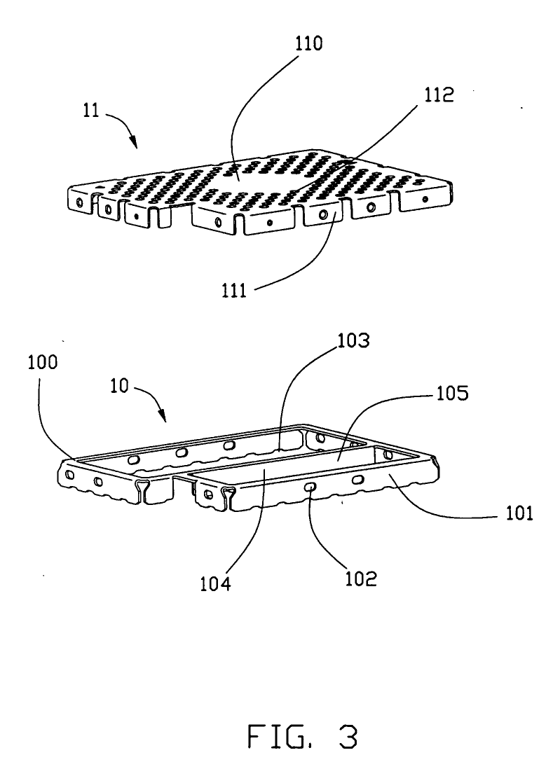

Referring to FIGS. 1-4, a shielding device 1 comprises a frame 10 and a top cover 11 for enclosing the frame 10. The frame 10 is mounted on a circuit board (not shown) by soldering and encloses a plurality of electronic elements (not shown) on the circuit board within its bound. Both of the frame 10 and the top cover 11 are made from a metal or a metal alloy.

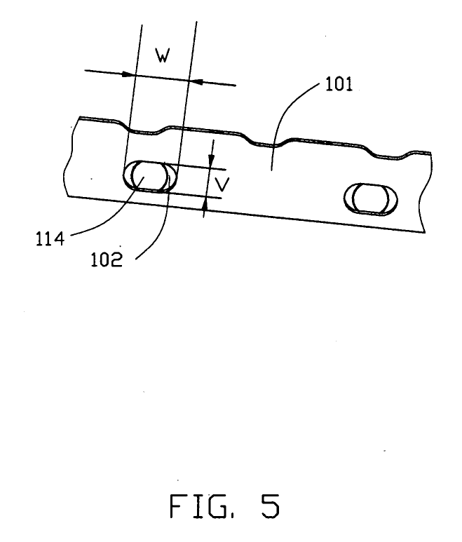

The frame 10 comprises a narrow, horizontal top wall 100 and a plurality of side walls 101 depending downwardly from outer edges of the top wall 100 wherein the side walls 101 are separated from each other. The frame 10 further defines a pair of openings 103, 105 and a separated wall 104 between said openings 103, 105. The openings 103, 105 are adapted for enclosing the electronic elements on the circuit board. The side walls 101 comprise a plurality of ellipse shaped mounting holes 102 defined therethrough. The dimension in the longitude direction of the mounting holes 102 is signed as “W”. The dimension in the height direction perpendicular to the longitude direction of the mounting holes 102 is signed as “V” which is shorter than “W” (seen in FIG. 5).

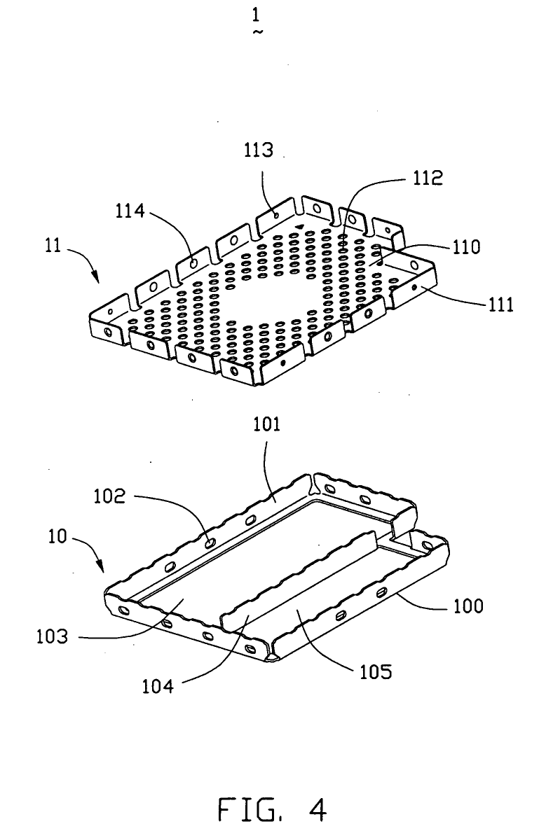

The top cover 11 comprises a body portion 110 and a plurality of holes 112 formed therein. A plurality of flanges 111 extends from outer edges of the body portion 110. Some flanges 111 define a number of dome shaped projections 114 projecting inwardly from the central portions of the flanges 111 for detachably engaging with corresponding mounting holes 102 of the frame 10. Other flanges 111 contain a plurality of half ball shaped protrusions 113 extending inwardly from the central portions of the flanges 111 for intervening against the frame 10. As shown in FIG. 4, each protrusion 113 is smaller than a projection 114.

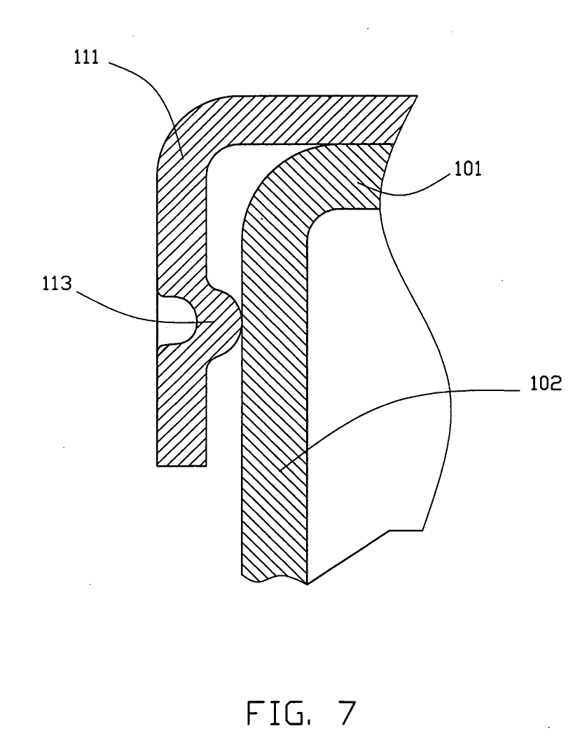

During assembly, the flanges 111 of the top cover 11 are brought to slide in the height direction over the side walls 101, and the dome shaped projections 114 easily encounter the mounting holes 102. The top cover 11 is firmly assembled to the frame 10 by the engagement of the projections 114 and the mounting holes 102 in the height direction. The protrusions 113 are intervening with the frame 10 thereby forming a small gap between the frame 10 and top cover 11 (seen in FIG. 7). During disassembly, the half ball shaped protrusions 113 slide over the side walls 101 and the dome shaped projections 114 are easily detached from the mounting holes 102, so that the top cover 11 can be separated from frame 10, thereby facilitating repair of the electronic elements when necessary.

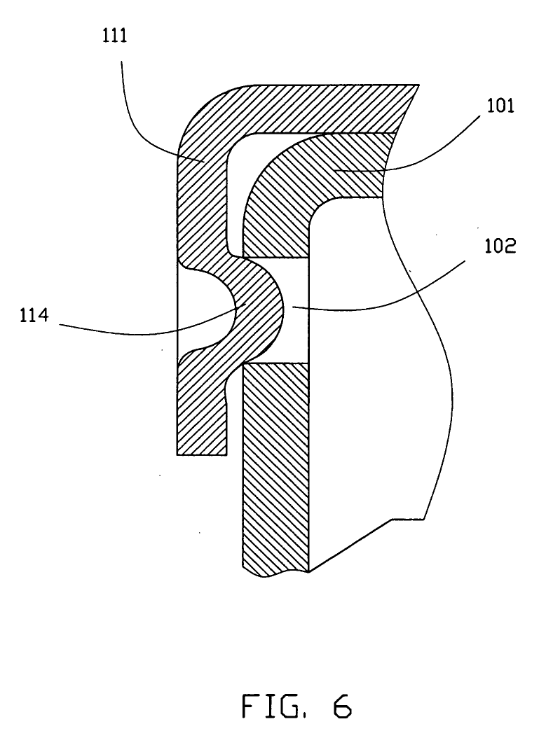

Referring to FIGS. 5-6, the dimension of mounting holes 102 “V” is substantially the same as that of the projections 114. Therefore, the projections 114 can firmly engaging with the mounting holes 102 in the height direction. Besides, the dimension “W” of each mounting hole 102 is larger than that of the projection 114, thereby providing a wide possible engaging area between the projections 114 and the mounting holes 102 in the longitude direction perpendicular to the height direction. It doesn't need precisely mating relationship between the projections 114 and the mounting holes 102 in the longitude direction, thereby facilitating the assembled process of the shielding device 1.

It is to be understood, however, that even though numerous, characteristics and advantages of the present invention have been set fourth in the foregoing description, together with details of the structure and function of the invention, the disclosed is illustrative only, and changes may be made in detail, especially in matters of number, shape, size, and arrangement of parts within the principles of the invention to the full extent indicated by the broad general meaning of the terms in which the appended claims are expressed.

What is claimed is:

1. A shielding device for providing EMI shielding for electronic elements on a circuit board, comprising:
a top cover having a body portion and a plurality of flanges extending downwardly from outer edges of the body portion, each flange forming a projection thereon; and
a frame mounted on the circuit board and enclosing the electronic elements, comprising a top wall and a plurality of side walls depending from edges of the top wall, each side wall defining a mounting hole for engaging with the projection of the top cover, the dimension of the mounting hole in a height direction of the shielding device being similar to that of the projection, while the dimension of the mounting hole in a direction perpendicular to the height direction being larger than that of the projection.

2. The shielding device as claimed in claim 1, wherein each projection is dome shaped and located in a central portion of the corresponding flange.

3. The shielding device as claimed in claim 1, wherein the projections are integrally extending inwardly from the flanges.

4. The shielding device as claimed in claim 1, wherein the flanges comprise a plurality of half ball shaped protrusions extending inwardly for intervening against the side walls.

5. The shielding device as claimed in claim 4, wherein the protrusions are smaller than the projections.

6. The shielding device as claimed in claim 1, wherein the side walls are separated from each other.

7. The shielding device as claimed in claim 1, wherein the shielding device is made from a metal or a metal alloy.

8. A shielding device for providing EMI shielding for electronic elements on a circuit board, comprising:
a top cover having a body portion and a plurality of flanges extending downwardly from outer edges of the body portion; and
a frame mounted on the circuit board and enclosing the electronic elements, comprising a top wall and a plurality of side walls depending from edges of the top wall,
either said flanges or said side walls defining a plurality of projection, and the other defining a plurality of corresponding mounting holes engaged with the corresponding projections, the dimension of the mounting hole in a height direction of the shielding device being not larger than that of the projection, while the dimension of the mounting hole in a direction perpendicular to the height direction being larger than that of the projection.
